(19) United States
(12) Patent Application Publication
(10) Pub. No.: US 2026/0324407 A1
(43) Pub. Date: Oct. 15, 2026

(54) CONNECTION STRUCTURES IN THREE-DIMENSIONAL SEMICONDUCTOR DEVICES AND SYSTEMS AND MANUFACTURING METHODS THEREOF

(71) Applicant: Yangtze Memory Technologies Co., Ltd., Wuhan (CN)

(72) Inventors: Fengtian HU, Wuhan (CN); Haijun HUANG, Wuhan (CN); Zhiliang XIA, Wuhan (CN)

(21) Appl. No.: 19/226,579

(22) Filed: Jun. 3, 2025

(30) Foreign Application Priority Data
Apr. 14, 2025 (CN) 202510465652.0

(51) Int. Cl. H10W 20/44; H10W 20/00; H10W 20/20; H10W 90/00

(52) U.S. Cl. CPC H10W 20/4473; H10W 20/023; H10W 20/057; H10W 20/064; H10W 20/076; H10W 20/089; H10W 20/20; H10W 20/4435; H10W 90/00

(57) ABSTRACT

Systems, devices, and manufacture methods for managing connection structures in a semiconductor device are provided. In one aspect, a semiconductor device includes a first semiconductor structure; a second semiconductor structure stacked over the first semiconductor structure along a first direction; and a connection structure extending from the second semiconductor structure into the first semiconductor structure along the first direction. The connection structure includes a conductive ink layer, and the conductive ink layer includes one or more conductive material and one or more organic polymer material.

### CROSS-REFERENCE TO RELATED APPLICATIONS

This application claims priority to Chinese Patent Application No. 202510465652.0, filed on Apr. 14, 2025, which is hereby incorporated by reference in its entirety.

### TECHNICAL FIELD

The present disclosure relates to semiconductor devices and fabrication processes for semiconductor devices.

### BACKGROUND

Semiconductor devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for connection structures in three-dimensional (3D) semiconductor devices and manufacturing methods thereof.

One aspect of the present disclosure features a semiconductor device, including: a first semiconductor structure; a second semiconductor structure stacked over the first semiconductor structure along a first direction; and a connection structure extending from the second semiconductor structure into the first semiconductor structure along the first direction, where the connection structure includes a conductive ink layer, and the conductive ink layer includes one or more conductive material and one or more organic polymer material.

In some implementations, one or more conductive material is greater than 85% in the conductive ink layer.

In some implementations, the one or more conductive material includes at least one of copper, silver or gold, and the one or more organic polymer material includes at least one of carbon, hydrogen, or oxygen.

In some implementations, the connection structure includes a first end coupled to the first semiconductor structure and a second end opposite to the first end along the first direction, and a width of the first end of the connection structure along a second direction is smaller than a width of the second end of the connection structure along the second direction.

In some implementations, the width of the first end of the connection structure along the second direction is greater than or equal to 0.5 micrometer.

In some implementations, a ratio of a height of the connection structure along the first direction to the width of the second end of the connection structure along the second direction is equal to or greater than 15.

In some implementations, the connection structure further includes a filler layer at least partially surrounded by the conductive ink layer, and the filler layer includes at least one of a conductive material or an organic polymer material.

In some implementations, the connection structure includes an isolation layer and a blocking layer between the isolation layer and the conductive ink layer, and the blocking layer includes at least one of titanium nitride (TiN), titanium (Ti), tantalum nitride (TaN) or tantalum (Ta).

In some implementations, the first semiconductor structure includes a conductive structure, and the conductive ink layer of the connection structure is in contact with the conductive structure of the first semiconductor structure.

In some implementations, at least one of the first semiconductor structure and the second semiconductor structure includes: a memory array including a plurality of memory cells; and a peripheral circuit coupled to the memory array and configured to control the memory array.

In some implementations, the semiconductor device includes a plurality of semiconductor structures including the first semiconductor structure and the second semiconductor structure, the plurality of semiconductor structures each having a conductive structure; and a plurality of connection structures including the connection structure, where the plurality of connection structures each has a first end and a second end opposite to the first end along the first direction, the second ends of the plurality of connection structures are aligned with one another, and the first end of each of the plurality of connection structures is coupled to the conductive structure of a corresponding one of the plurality of semiconductor structures, and where at least two of the plurality of connection structures have different height along the first direction.

In some implementations, the first semiconductor structure includes a first dielectric structure, the second semiconductor structure includes a second dielectric structure in contact with the first dielectric structure, and the connection structure extends through the second dielectric structure of the second semiconductor structure into the first dielectric structure of the first semiconductor structure.

Another aspect of the present disclosure features a method including: providing a first semiconductor structure; providing a second semiconductor structure stacked over the first semiconductor structure along a first direction; forming an opening extending through the second semiconductor structure into the first semiconductor structure along the first direction; at least partially filling the opening with a conductive ink liquid, where the conductive ink liquid includes one or more conductive material and one or more organic polymer material; and sintering the conductive ink liquid to form a conductive ink layer in the opening, where the conductive ink layer includes the one or more conductive material and at least one of the one or more organic polymer material.

In some implementations, the method includes at least partially filling a process chamber with at least one of an inert gas or a reducing gas, where sintering the conductive ink liquid to form the conductive ink layer includes sintering the conductive ink liquid to form the conductive ink layer in the process chamber.

In some implementations, sintering the conductive ink liquid to form the conductive ink layer includes: sintering the conductive ink liquid to form the conductive ink layer at a temperature lower than 300 degree Celsius.

In some implementations, the one or more conductive material includes at least one of copper, silver or gold, and the one or more organic polymer material includes at least one of carbon, hydrogen, or oxygen.

In some implementations, a percentage of the one or more organic polymer material in the conducive ink liquid is greater than a percentage of the one or more organic polymer material in the conducive ink layer.

In some implementations, the method includes forming an isolation layer; forming a blocking layer between the isolation layer and the conductive ink layer in the opening; and forming a filler layer, where the conducive ink layer is between the filler layer and the blocking layer.

In some implementations, the first semiconductor structure includes a conductive structure, and forming the opening extending through the second semiconductor structure into the first semiconductor structure includes: forming the opening extending through the second semiconductor structure into the first semiconductor structure to expose a portion of the conductive structure.

In some implementations, the method includes before at least partially filling the opening with the conductive ink liquid, removing the isolation layer at a first end of the opening, the first end of the opening being coupled to the first semiconductor structure.

In some implementations, forming the opening includes: forming the opening such that the opening includes a first end coupled to the first semiconductor structure and a second end opposite to the first end along the first direction, a width of the first end of the opening being smaller than a width of the second end of the opening along a second direction.

In some implementations, forming the opening includes: forming the opening such that the width of the first end of the opening along the second direction is greater than or equal to 0.5 micrometer.

In some implementations, the method includes: providing a plurality of semiconductor structures including the first semiconductor structure and the second semiconductor structure, the plurality of semiconductor structures each having a conductive structure; and forming a plurality of openings including the opening, where the plurality of openings each has a first end and a second end opposite to the first end along the first direction, the first ends of the plurality of openings are aligned with one another, and the second end of each of the plurality of openings exposes a portion of the conductive structure of a corresponding one of the plurality of semiconductor structures, and where at least two of the plurality of openings have different height along the first direction.

Another aspect of the present disclosure features a system, including: a memory die including: a first semiconductor structure; a second semiconductor structure stacked over the first semiconductor structure along a first direction; and a connection structure extending from the second semiconductor structure into the first semiconductor structure along the first direction, where the connection structure includes a conductive ink layer, and the conductive ink layer includes one or more conductive material and one or more organic polymer material; and a base die coupled to the memory die, where the base die and the memory die are stacked along the first direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a schematic view of a cross-section of an example of a memory device.

FIG. 2 illustrates a schematic view of a cross-section of an example of a semiconductor device.

FIG. 3A illustrates an example of a bottom part of a connection structure.

FIG. 3B illustrates another example of a bottom part of a connection structure.

FIG. 3C illustrates yet another example of a bottom part of a connection structure.

FIG. 3D illustrates an enlarged view of an example of connection structures.

FIGS. 4A-4D illustrate cross-sectional views of a semiconductor device at various stages of a manufacture process.

FIG. 5 illustrates a flow chart of a process of an example of method to form a semiconductor device.

FIG. 6 illustrates a block diagram of a system having one or more semiconductor devices.

Like reference numbers and designations in the various drawings indicate like elements. It is to be understood that the various exemplary implementations shown in the figures are merely illustrative representations and are not necessarily drawn to scale.

### DETAILED DESCRIPTION

In a 3D memory device (e.g., a high bandwidth memory device), a through-silicon via (TSV) (also called connection structures in the present disclosure) can be formed to pass through vertical stacking of memory dies, allowing direct communications between stacked memory dies and a base die. To form TSVs, a conductive material can be first deposited into a deep hole using physical vapor deposition (PVD) to form a seed layer, and the seed layer can be subsequently used for an electroplating process. However, due to a high aspect ratio (e.g., larger than 15 or 20) of the deep hole and the limitations of PVD techniques, the conductive material (e.g., copper) may not reach the bottom of the deep hole, leading to void formation. These voids can cause poor contact between the TSVs and conductive layers in the memory dies, thereby affecting the performance and reliability of the 3D memory device. In some cases, atomic layer deposition (ALD) can be used to fill the bottom of the deep hole with conductive materials. However, ALD techniques can come with high production costs.

Implementations of the present disclosure provide semiconductor devices and methods to form such semiconductor devices. In some implementations, a semiconductor device includes a first semiconductor structure; a second semiconductor structure stacked over the first semiconductor structure along a first direction; and a connection structure extending from the second semiconductor structure into the first semiconductor structure along the first direction. The connection structure includes a conductive ink layer, and the conductive ink layer includes one or more conductive material and one or more organic polymer material.

Implementations of the present disclosure can provide one or more of the following technical advantages and/or benefits. For example, implementations can reduce or eliminate void formation at the bottom of the deep hole by using a conductive ink material, thereby improving yield, performance and reliability of a semiconductor device. The conductive ink, with its flow characteristics, can uniformly fill deep holes that have high aspect ratio. This can reduce or eliminate the formation of voids at the bottom of the deep holes. Additionally, implementations of the present disclosure can improve the efficiency of forming connection structures (e.g., TSVs), because conductive ink filling and sintering may take a relatively short time (e.g., only about a few minutes). As a result, production cycle times and manufacturing costs can be reduced. Further, the conductive ink material can be applied to the deep holes through printing techniques that are more cost-effective than ALD, further reducing the production costs.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

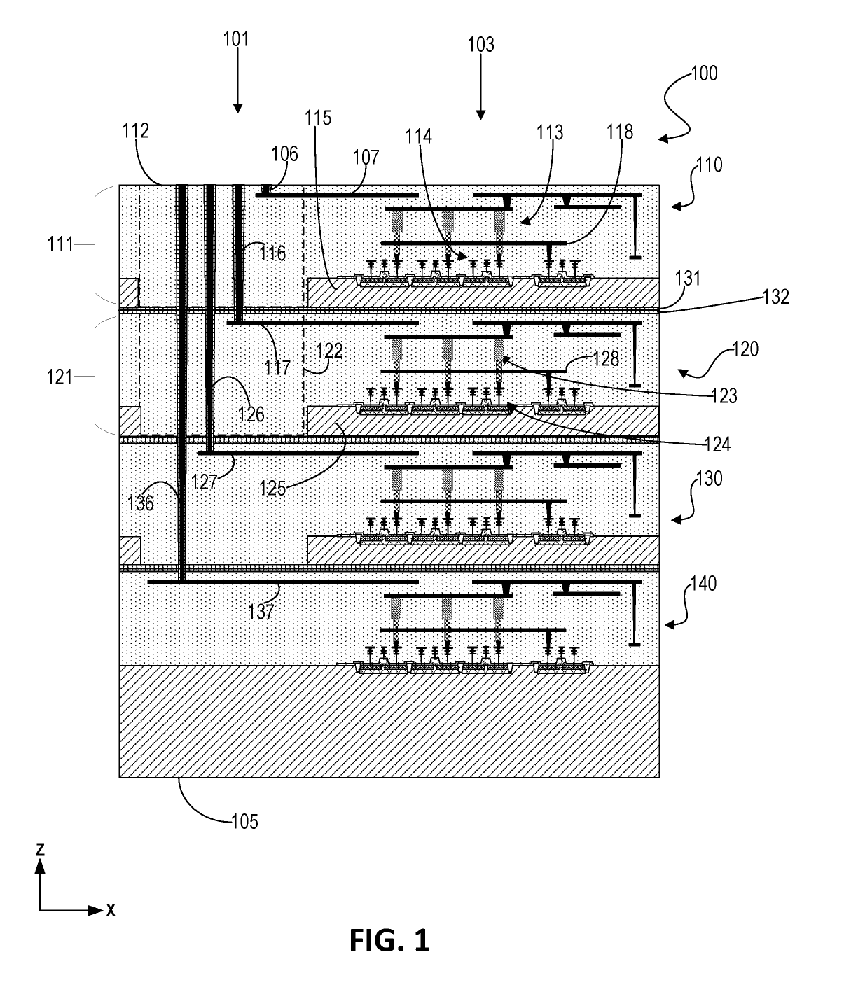

FIG. 1 illustrates a schematic view of a cross-section of a memory device 100, according to some implementations of the present disclosure. The memory device 100 includes a first semiconductor chip 110 and a second semiconductor chip 120 stacking with the first semiconductor chip 110 along the Z-direction. It is noted that more semiconductor chips may be stacked with the first semiconductor chip 110 and the second semiconductor chip 120. As shown in FIG. 1, the memory device 100 can include four semiconductor chips 110-140. For illustration purpose, the first semiconductor chip 110 and the second semiconductor chip 120 will be used as an example in the subsequent discussions for simplicity. The semiconductor chips can also be referred to as semiconductor structures or memory dies in the present disclosure.

The first semiconductor chip 110 includes a first semiconductor structure 111 and a first dielectric structure 112 extending through the first semiconductor structure 111. The second semiconductor chip 120 includes a second semiconductor structure 121 and a second dielectric structure 122 extending through the second semiconductor structure 121. In some implementations, the first semiconductor structure 111 and the second semiconductor structure 121 are memory structures that include at least one memory array, and each memory array can include a plurality of memory cells. The semiconductor structures 111, 121 can be DRAM memory devices, NAND memory devices, ferroelectric memory devices, or any other suitable memory devices. The first and second dielectric structure 112, 122 can be respectively located in the connection region 101 of the semiconductor chips 110, 120. In some implementations, the first semiconductor structure 111 includes a first memory structure 113 and a first peripheral structure 114 stacking in the Z-direction. In some implementations, the first peripheral structure 114 is formed on a first substrate 115. In some implementations, the first substrate 115 is a silicon substrate. In some implementations, the second semiconductor structure 121 includes a second memory structure 123 and a second peripheral structure 124 stacking in the Z-direction. In some implementations, the second peripheral structure 124 is formed on a second substrate 125. In some implementations, the second substrate 125 is a silicon substrate. The first and second memory structure 113, 123, and the first and second peripheral structures 114, 124 can be formed in the device region 103 of the corresponding semiconductor chips 110, 120. For ease of description, the first dielectric structure 112 and the second dielectric structure 122 are shown in dash lines in FIG. 1, and the first dielectric structure 112 and the second dielectric structure 122 may be formed by the same material of dielectric portions of the first semiconductor structure 111 and the second semiconductor structure 121.

In some implementations, each of the peripheral structures 114, 124 is configured to control the operation of memory cells in the corresponding memory structure 113, 123. In some implementations, each of the peripheral structures 114, 124 includes, without limitation to, a data buffer/sense amplifier, a column decoder/bit line driver, a row decoder/word line driver, input-output (I/O) circuitry, address decoders, row and column address buffers, read/write control logic, row and column decoders, clock generation and control, Error Correction Code (ECC) logic, power management circuitry, any combination thereof, or any other suitable circuitry.

A first connection structure 116 extends along the Z-direction in the first dielectric structure 112 and is in contact with a first conductive structure 117 of the first semiconductor chip 110. A second connection structure 126 extends along the Z-direction in the first dielectric structure 112 and the second dielectric structure 122 and is in contact with a second conductive structure 127 of the second semiconductor chip 120. The first dielectric structure 112 and the second dielectric structure 122 are aligned in the Z-direction. As shown in FIG. 1, In some implementations, the first and second connection structures 116, 126 do not extend through any substrate (e.g., substrate 115, 125), but only through dielectric materials.

In some implementations, the first conductive structure 117 and the second conductive structure 127 extend along the X-direction perpendicular to the Z-direction. In some implementations, the first conductive structure 117 is formed below the first substrate 115, and the second conductive structure 127 is formed below the second substrate 125, as shown in FIG. 1. In some implementations, the first conductive structure 117 is formed above the first substrate 115 and the second conductive structure 127 is formed above the second substrate 125.

In some implementations, the first semiconductor chip 110 includes a first dielectric bonding layer 131, the second semiconductor chip 120 includes a second dielectric bonding layer 132, and the first semiconductor chip 110 and the second semiconductor chip 120 are bonded through the first dielectric bonding layer 131 and the second dielectric bonding layer 132. In other words, the first semiconductor chip 110 and the second semiconductor chip 120 are bonded through only the dielectric bonding layers 131 and 132, and no metal structure or metal contact is used for bonding the first semiconductor chip 110 and the second semiconductor chip 120. In some implementations, only silicon oxide is used for bonding the first semiconductor chip 110 and the second semiconductor chip 120. It is noted that, after the bonding operation, since the dielectric bonding layers 131 and 132 are both formed by silicon oxide, the boundary may not be found or may not be obvious in the final product.

In some implementations, the first memory structure 113 is bonded to the first peripheral structure 114 through a hybrid bonding layer 118. In some implementations, the hybrid bonding layer 118 includes a dielectric bonding layer and a conductive bonding structure. In other words, the first memory structure 113 is bonded to the first peripheral structure 114 through both dielectric material and conductive material. In some implementations, the second memory structure 123 is bonded to the second peripheral structure 124 through a hybrid bonding layer 128. In some implementations, the hybrid bonding layer 128 includes a dielectric bonding layer and a conductive bonding structure. In other words, the second memory structure 123 is bonded to the second peripheral structure 124 through both dielectric material and conductive material.

The first connection structure 116 extends along the Z-direction in the first dielectric structure 112 and in contact with the first conductive structure 117. The second connection structure 126 extends along the Z-direction in both the first dielectric structure 112 and the second dielectric structure 122 and in contact with the second conductive structure 127. In some implementations, the first connection structure 116 and the second connection structure 126 are arranged side-by-side along the X-direction, as shown in FIG. 1. In some implementations, the length of the second connection structure 126 in the Z-direction is greater than the length of the first connection structure 116 in the Z-direction.

In some implementations, a top end of the first connection structure 116 and a top end of the second connection structure 126 are coplanar in the X-direction. In other words, the top end of the first connection structure 116 and the top end of the second connection structure 126 both extend to the top surface of the first semiconductor chip 110. Because a planarization operation is performed on the top surface of the first semiconductor chip 110, the top end of the first connection structure 116 and the top end of the second connection structure 126 are coplanar in the X-direction. In some implementations, the bottom end of the first connection structure 116 is in contact with the first conductive structure 117, and the bottom end of the second connection structure 126 is in contact with the second conductive structure 127.

In some implementations, the first conductive structure 117 may be directly connected to the memory peripheral area, e.g., the first peripheral structure 114. In some implementations, the first conductive structure 117 and the conductive structure of the first peripheral structure 114 may be formed by the same operation. In some implementations, the second conductive structure 127 may be directly connected to the memory peripheral area, e.g., the second peripheral structure 124. In some implementations, the second conductive structure 127 and the conductive structure of the second peripheral structure 124 may be formed by the same operation.

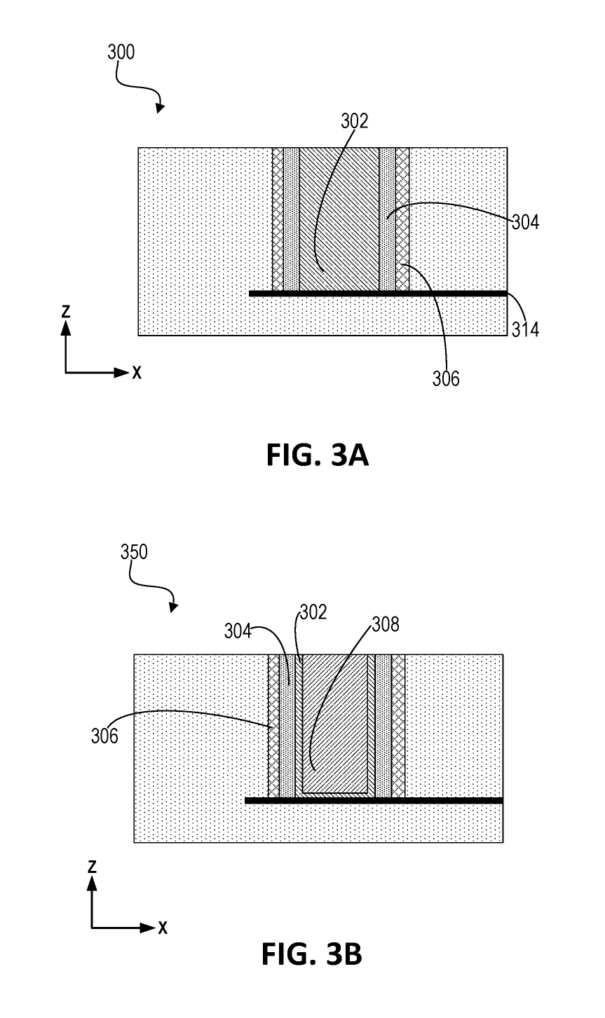

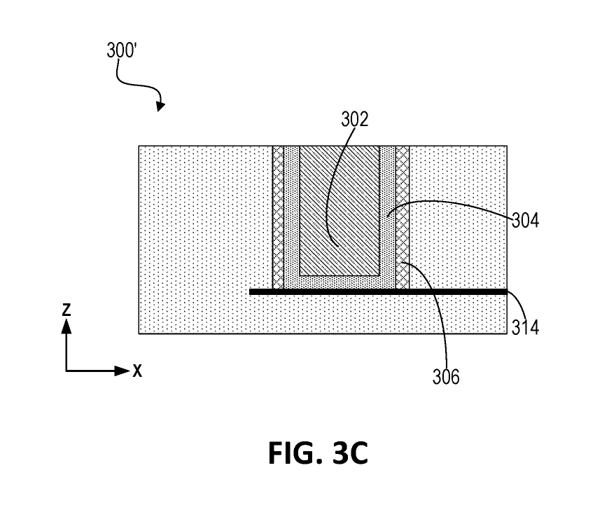

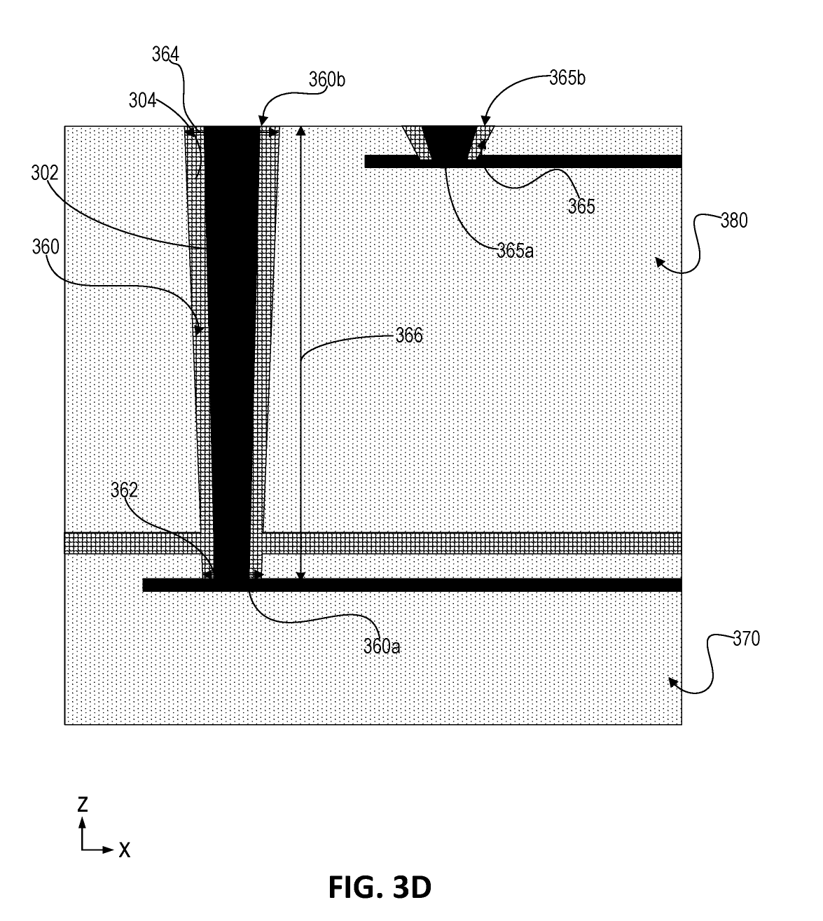

The first semiconductor structure 111 includes the first substrate 115, and the first dielectric structure 112 penetrates the first substrate 115 along the Z-direction. The second semiconductor structure 121 includes the second substrate 125, and the second dielectric structure 122 penetrates the second substrate 125 along the Z-direction. As described in greater detail below in reference to FIGS. 3A-3C, in some implementations, the first and second connection structure 116, 126 may each include a conductive ink layer.

By directly connecting the memory peripheral area with the connection structures (e.g., the first and second connection structure 116, 126), the power transition can be improved. Furthermore, by pre-removing the substrate in the area of dielectric structures (e.g., first dielectric structure 112 and the second dielectric structure 122), the technological difficulty of forming connection structures can be reduced. The connection structures (e.g., the first and second connection structure 116, 126) can also be referred to as through-silicon-via (TSV) in some cases. It is to be understood that despite the name “through-silicon” via, TSVs may not necessarily extend through any silicon substrate. Instead, they may only extend through dielectric structures, as illustrated in FIG. 1.

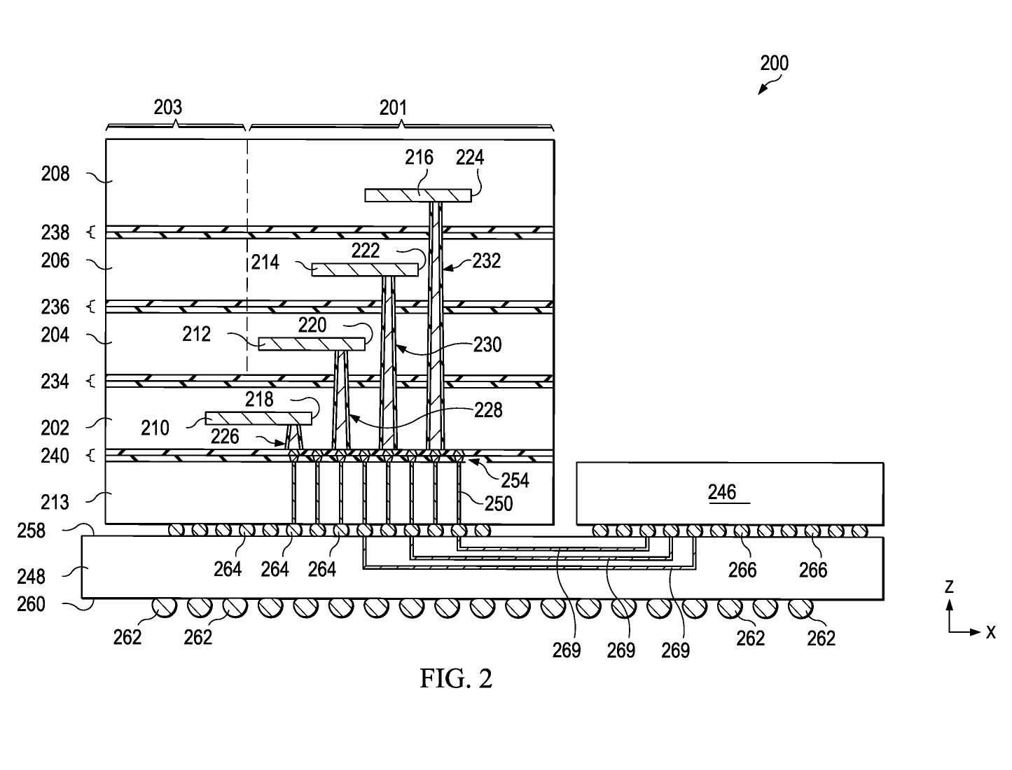

FIG. 2 illustrates a side view of a 3D semiconductor device 200, according to some aspects of the present disclosure. The semiconductor device 200 can be a high bandwidth memory (HBM) device. The semiconductor device 200 can include memory dies 202-208, a base die 213, a computing die 246, and an interposer 248. Memory dies 202-208 can be examples of first semiconductor chip 110, or second semiconductor chip 120 of FIG. 1. For example, memory die 202 can be the first semiconductor chip 110 of FIG. 1, memory die 204 can be the second semiconductor chip 120 of FIG. 1, memory die 206 can be the third semiconductor chip 130 of FIG. 1, and memory die 208 can be the fourth semiconductor chip 140 of FIG. 1. Memory die 202-208 can include at least one memory array, and each memory array can include a plurality of memory cells. The memory dies 202-208 can be DRAM memory dies, NAND memory dies, ferroelectric memory dies, or any other suitable memory dies.

Memory dies 202-208 and base die 213 can be stacked (e.g., sequentially) along the Z direction. Base die 213 and computing die 246 can be integrated on different positions of the interposer 248 along the X direction.

In some implementations, base die 213 includes a base control circuitry that is configured to control the operations of memory dies 202, 204, 206, 208. The base control circuitry of base die 213 can be coupled to the control circuits in the control substructures (e.g., first peripheral structure 114, second peripheral structure 124) of the memory dies 202, 204, 206, 208.

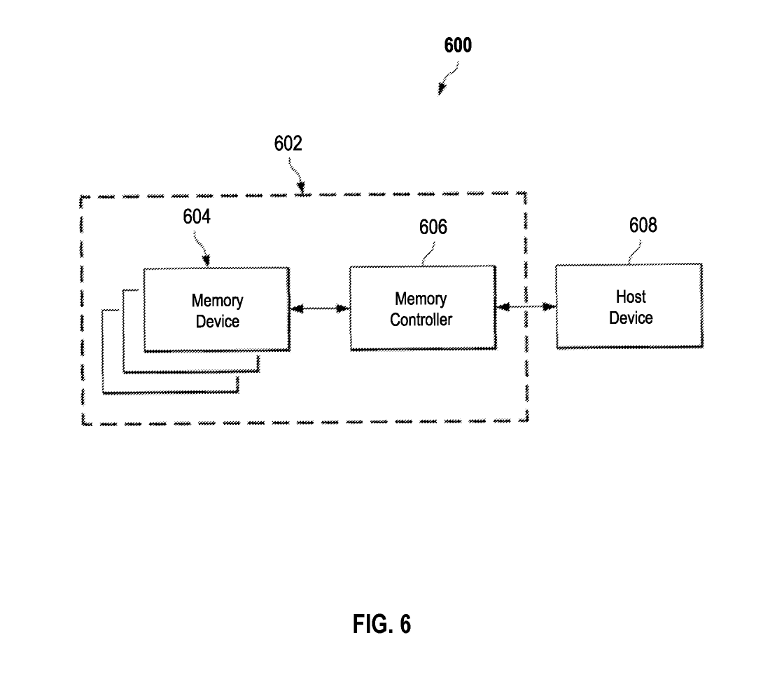

The base die 213 can be coupled to the computing die 246 through the interposer 248. The interposer 248 has a surface 258 and a surface 260. The vias 250 in the base die 213 can be connected to conductive terminals 264 on surface 258 of the interposer 248. The computing die 246 can be connected to conductive terminals 266 on surface 258 of the interposer 248. The semiconductor device 200 can include conductive terminals 262 connected to the surface 260 of the interposer 248. Conductive terminals 264, 266, and 262 can be coupled through conductive lines (e.g., conductive lines 269 as shown in FIG. 2) in the interposer 248. The conductive terminals 262 can be coupled to an external device (e.g., an external host device 608 of FIG. 6). In some implementations, the conductive terminals 264, 266, and 262 can be micro bumps, solder bumps, or any other suitable structures. It is understood that in practice, base die 213, computing die 246, and interposer 248 can be integrated together using any suitable packaging technology including, for example, Chip-on-Wafer-on-Substrate (CoWoS).

As shown in FIG. 2, the semiconductor device 200 includes bonding layers (e.g., bonding layers 234, 236, and 238) between adjacent memory dies of memory dies 202-208 and a bonding layer 240 between memory die 202 and base die 213. Each of these bonding layers can include a dielectric material such as silicon oxide.

With continued reference to FIG. 2, the semiconductor device 200 includes a connection area 201 that includes connection structures 226-232 and a device area 203. The connection area 201 can be the connection region 101 of FIG. 1, and the device area 203 can be the device region 103 of FIG. 1. Connection structures 226-232 can be examples of connection structures 300, 350, 300’ of FIGS. 3A-3C. Connection structures 226-232 extend along the vertical direction (e.g., the Z direction) and are coupled to conductive structures 210-216, respectively. Connection structure 226 extends into memory die 202 and is connected to conductive structure 210 of memory die 202 without extending through bonding layer 234. Connection structure 228 extends through memory die 202 and bonding layer 234 into memory die 204 without extending through bonding layer 236. Connection structure 228 is connected to conductive structure 212 of memory die 204 without extending through conductive structure 210. Connection structure 230 extends through memory die 202-204 and bonding layers 234 and 236 into memory die 206 without extending through bonding layer 238. Connection structure 230 is connected to conductive structure 214 of memory die 206 without extending through conductive structures 210 and 212. Connection structure 232 extends through memory dice 202-206 into memory die 208 without extending through memory die 208. Connection structure 232 is connected to conductive structure 216 of memory die 208 without extending through conductive structures 210-214. In some implementations, the conductive structures 210-216 are conductive layers.

The conductive structures 210-216 can form a stepped structure to allow each of connection structures 226-232 to connect to a corresponding one of conductive structures 210-216 without extending through other conductive structures. In some implementations, as shown in FIG. 2, conductive structures 210-216 can have the same length and are offset along the X direction. In other words, the ends 218-224 (e.g., the ends on the right side) of conductive structures 210-216 can be offset along the X direction. Specifically, connection structure 228 is between end 218 of conductive structure 210 and end 220 of conductive structure 212 along the X direction. That is, end 218 of conductive structure 210 is between connection structure 226 and connection structure 228 along the X direction. This way, connection structure 228 can extend through memory die 202 and bypass conductive structure 210 of memory die 202. Similarly, connection structure 230 is between end 220 of conductive structure 212 and end 222 of conductive structure 214 along the X direction, so that connection structure 230 can extend through memory dice 202-204 and bypass conducive layers 210-212. In addition, connection structure 232 is between end 222 of conductive structure 214 and end 224 of conductive structure 216 along the X direction, so that connection structure 232 can extend through memory dice 202-206 and bypass conducive layers 210-314.

In some implementations, bonding layers 234, 236, and 238 can be referred to as direct bonding layers and can have structures similar to that of dielectric bonding layer 131, 132 described in FIG. 1. Each of bonding layers 234, 236, and 238 can include at least one dielectric material and exclude a conductive bonding contact. In some implementations, bonding layer 240 can be referred to as a hybrid bonding layer. Bonding layer 240 can include bonding contacts (e.g., conductive bonding contacts 254 as shown in FIG. 2) and at least one dielectric material isolating the bonding contacts. Conductive bonding contacts 254 can be configured to connect memory die 202 and base die 213. In some implementations, memory die 202 can include an interconnect layer (not shown in FIG. 2) in contact with bonding layer 240. The interconnect layers can include interconnect conductive structures. Each of connection structures 226-232 can be coupled to the interconnect layer of memory die 202. The interconnect layer of memory die 202 can be coupled to base die 213 through conductive bonding contacts 254 in the bonding layer 240. Base die 244 includes vias 250 extending through base die 213 along the Z direction and being connected to conductive bonding contacts 254. Each of the connection structures 226-232 is coupled to a corresponding one or more vias of the vias 250 through a corresponding conductive bonding contact 254. In some implementations, vias 250 can be TSVs.

In some implementations, as shown in FIG. 2, memory dice 202-206 can have a reduced thickness (along the Z direction) by having their substrates thinned. The topmost memory die 208 (e.g., the one among memory dice 202-208 that is farthest away from base die 213) may not be thinned. As a result, a thickness of each of memory dice 202-206 can be smaller than a thickness of memory die 208. The thickness of each of memory dice 202- 208 can be in any suitable range (e.g., between 2 µm and 20 µm).

Although not shown, it is to be understood that the interposer 248, the computing die 246, the base die 213, and the memory dies 202, 204, 206, 208 can be stacked sequentially along Z direction, such that the computing die 246 is between the base die 213 and the interposer 248 along Z direction. Similar to the vias 250 of the base die 213, computing die 246 can include through-vias extending through the computing die 246 along the Z direction and being coupled to the interposer 248 through corresponding conductive terminals.

FIG. 3A illustrates an example of a bottom part of a connection structure 300 according to one or more implementations of the present disclosure. The connection structure 300 can be any one of the connection structures 106, 116, 126, 136 of FIG. 1, or any one of the connection structures 226, 228, 230, 232 of FIG. 2.

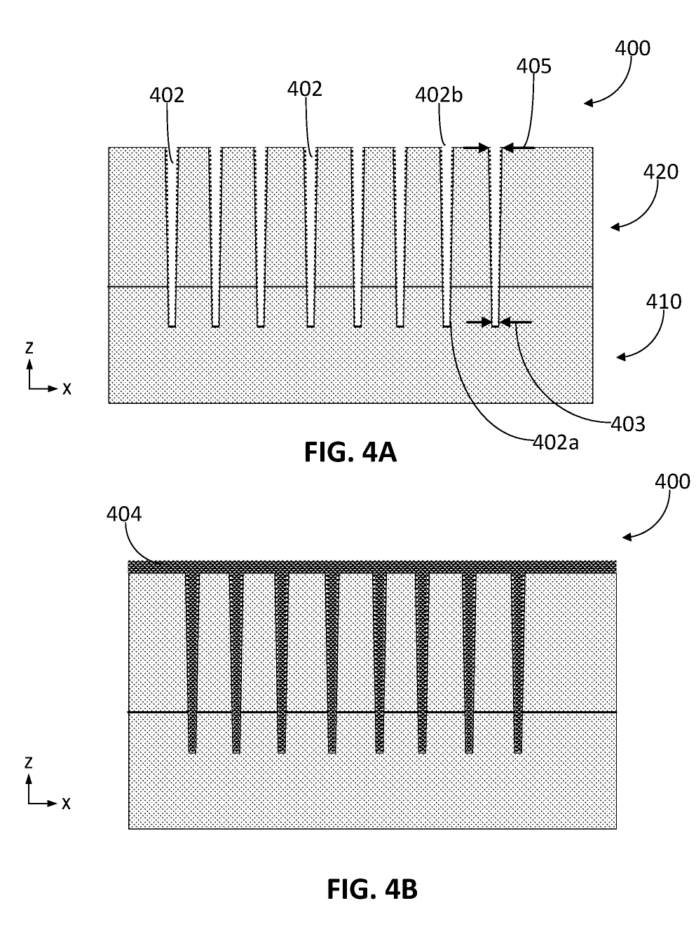

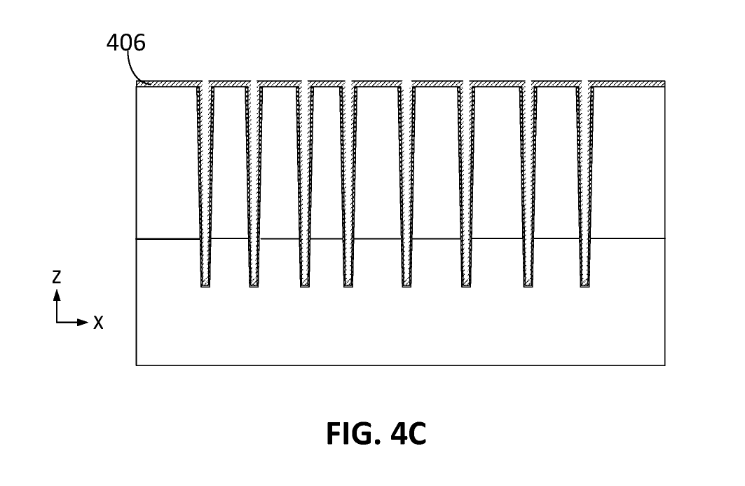

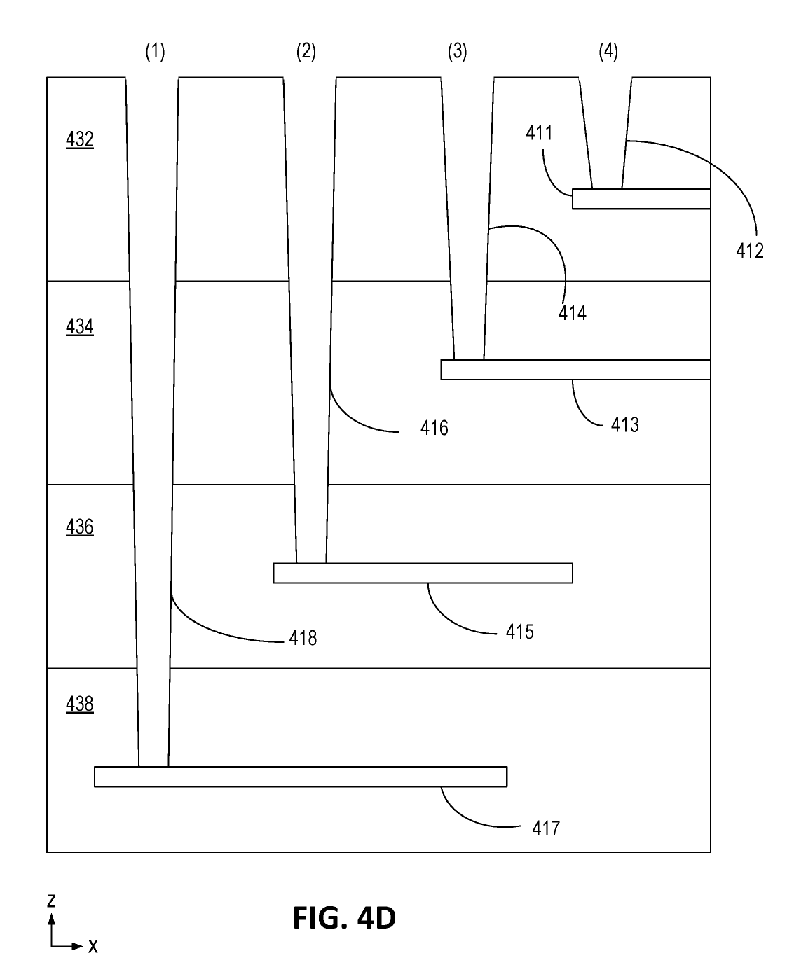

As shown in FIG. 3A, the connection structure 300 includes a conductive ink layer 302. In some examples, the conductive ink layer 302 can include conductive particles and binder. The binder can be used to hold the conductive particles together. The conductive particles can include metallic particles (e.g., silver, copper, gold, and/or nickel), carbon-based materials (e.g., graphene, carbon nanotubes, or carbon black), and/or conductive polymers (e.g., PEDOT:PSS (poly(3,4-ethylenedioxythiophene) polystyrene sulfonate). The binder can include polymer or resin. As described with further details below in reference to FIGS. 4A-4D, the conductive ink layer 302 can be formed by sintering conductive ink liquid. The conductive ink liquid can have good fluidity and strong filling capability, allowing a deep opening (e.g., opening 402 of FIGS. 4A-4C) to be uniformly filled with the conductive ink liquid. This reduces or eliminates the formation of voids at the bottom end of the connection structure 300, thereby improving yield, performance and reliability of the semiconductor device.

In some implementations, the conductive ink layer 302 includes one or more conductive material and one or more organic polymer material. In some implementations, the one or more conductive material includes at least one of copper, silver or gold, and the one or more organic polymer material includes at least one of carbon, hydrogen, or oxygen. In an example, the conductive ink layer 302 includes copper and organic polymer materials. In another example, the conductive ink layer 302 includes silver and organic polymer materials. Examples of organic polymer materials include, without limitation to, poly(3,4-ethylenedioxythiophene) (PEDOT), polyaniline (PANI), polyethylene dioxythiophene (PEDOT), polyvinylidene fluoride (PVDF), polyurethane (PU), polyvinylpyrrolidone (PVP), polyvinyl alcohol (PVA), polyethylene glycol (PEG), polyimide (PI), ethyl cellulose, polystyrene (PS), polyethylene terephthalate (PET), epoxy resins, acrylic polymers, or any other suitable material.

In some implementations, the one or more conductive material is greater than 85% (e.g., mass percentage, or mole percentage) in the conductive ink layer 302. For example, a ratio between the conductive material and the organic polymer material can be about 9: 1 (e.g., mass ratio, or mole ratio).

As illustrated in FIG. 3A, in some implementations, the connection structure 300 includes an isolation layer 306 and a blocking layer 304 between the isolation layer 306 and the conductive ink layer 302. In some other implementations, the connection structure 300 includes the blocking layer 304 but does not include the isolation layer 306, as illustrated in FIG. 3D.

In some implementations, the blocking layer 304 includes at least one of titanium nitride (TiN), titanium (Ti), tantalum nitride (TaN) or tantalum (Ta). In some examples, the blocking layer 304 can include titanium nitride (TiN) and/or titanium (Ti). In some other examples, the blocking layer 304 can include tantalum nitride (TaN) and/or tantalum (Ta). The isolation layer 306 can include dielectric materials including, but not limited to, silicon oxide, silicon nitride, silicon oxynitride, or any combination thereof. In an example, the isolation layer 306 can include silicon oxide.

In example implementations where the blocking layer 304 includes conductive material, as illustrated in FIG. 3C, in the connection structure 300’, the blocking layer 304 can have a portion that is between the conductive ink layer 302 and the conductive structure 314. Therefore, the conductive ink layer 302 can be coupled to the conductive structure 314 through the blocking layer 304.

As illustrated in FIG. 3A, the conductive ink layer 302 can be coupled to a conductive structure 314 at the bottom part of the connection structure 300. The conductive structure 314 can be any one of the conductive structures 107, 117, 127, 137 of FIG. 1, or any one of the conductive structures 210, 212, 214, 216 of FIG. 2. As noted above, the connection structure 300 can couple out the memory arrays and/or peripheral circuits of corresponding semiconductor chips (e.g., a memory die) to other semiconductor structures (e.g., a base die) through the conductive structure 314.

FIG. 3B illustrates another example of a bottom part of a connection structure 350 according to one or more implementations of the present disclosure. The connection structure 350 can be any one of the connection structures 106, 116, 126, 136 of FIG. 1, or any one of the connection structures 226, 228, 230, 232 of FIG. 2. The connection structure 350 differs from the connection structure 300 primarily in that the connection structure 350 further includes a filler layer 308 in the inner portion of the connection structure 350, and the filler layer 308 is at least partially surrounded by the conductive ink layer 302. In some implementations, the filler layer 308 includes at least one of a conductive material or an organic polymer material. For example, the filler layer 308 can include copper, tungsten, silver, and/or nickel. The filler layer 308 can also include organic polymer materials described herein. In some implementations, as described with greater details below in reference to FIGS. 4A-4D, the filler layer 308 includes a conductive material, and the filler layer 308 can be formed by electroplating by using the conductive ink layer 302 as a seed layer, or be formed by other deposition methods (e.g., CVD, PVD, ALD, etc.).

FIG. 3D illustrates an enlarged view of an example of connection structures 360, 365 according to one or more implementations of the present disclosure. The connection structure 360, 365 can be any one of the connection structures 106, 116, 126, 136 of FIG. 1, or any one of the connection structures 226, 228, 230, 232 of FIG. 2. For example, the connection structure 360 can be the connection structure 116 of FIG. 1, and/or the connection structure 228 of FIG. 2. The connection structure 365 can be the connection structure 106 of FIG. 1, and/or the connection structure 226 of FIG. 2. For illustration purpose, the connection structure 360 will be used as an example in the subsequent discussions for simplicity.

As illustrated in FIG. 3D, the connection structure 360 includes a first end 360a coupled to a corresponding semiconductor structure (e.g., a first semiconductor structure 370) and a second end 360b opposite to the first end 360a along Z direction. The second end 360b of the connection structure 360 can be the end that is aligned with other ends of the connection structures. For example, as illustrated in FIG. 3D, the second end 360b of the connection structure 360 is aligned or coplanar with the second end 365b of the connection structure 365. In another example, tuning briefly back to FIG. 2, the second end of the connection structures 226, 228, 230, 232 can be the ends that are coplanar or aligned with one another and the ends that are coupled to the conductive bonding contacts 254.

In contrast, with continued reference to FIG. 3D, the first ends of the connection structures can extend into different depths into different semiconductor structures. For example, the first end 360a of the connection structure 360 extends into the first semiconductor structure 370, while the first end 365a of the connection structure 365 extends into the second semiconductor structure 380. The first semiconductor structure 370 can be the second semiconductor chip 120 of FIG, 1, or the memory die 204 of FIG. 2. The second semiconductor structure 380 can be the first semiconductor chip 110 of FIG, 1, or the memory die 202 of FIG. 2.

As shown in FIG. 3D, in some implementations, a width 362 of the first end 360a of the connection structure 360 along a second direction (e.g., X direction) is smaller than a width 364 of the second end 360b of the connection structure 360 along the second direction. The width difference can result from an etching process, as described below with reference to FIGS. 4A-4D. In some implementations, the width 362 of the first end 360a of the connection structure 360 is greater than or equal to 0.5 micrometer. With being limited to any particular theory, wider width can be more effectively filled with materials (e.g., conductive ink materials), allowing for consistent and uniform material distribution and thereby reducing voids or air gaps at the first end 360a.

In some implementations, a ratio of a height 366 of the connection structure 360 along Z direction to the width 364 of the second end 360b of the connection structure 360 along X direction is equal to or greater than 15. The height 366 can be measured by a distance between the first end 360a and the second end 360b of the connection structure 360. Turning briefly back to FIGS. 1 and 2, different connection structures can have different depths/heights and extend into different memory dies or semiconductor chips along a vertical direction (e.g., Z direction) that is perpendicular to a substrate surface (e.g., substrate surface 105 of FIG. 1). Different connection structures may have the same or different widths along a lateral direction (e.g., X direction) that is parallel to the substrate surface.

FIGS. 4A-4D illustrate cross-sectional views of a semiconductor device 400 at various stages of a manufacture process. The semiconductor device 400 can be the memory device 100 of FIG. 1, the semiconductor device 200 of FIG. 2, any one of the semiconductor chips 110, 120, 130, 140 of FIG. 1, any one of the memory dies 202, 204, 206, 208 of FIG. 2, the connection structure 300 of FIG. 3A, the connection structure 350 of FIG. 3B, the connection structure 300’ of FIG. 3C, or connection structures 360, 365 of FIG. 3D.

As illustrated in FIG. 4A, a first semiconductor structure 410 and a second semiconductor structure 420 are provided. The second semiconductor structure 420 can be stacked over the first semiconductor structure 410 along a first direction (e.g., Z direction). The first semiconductor structure 410 can be the second semiconductor chip 120 of FIG. 1, the memory die 204 of FIG. 2, or the first semiconductor structure 370 of FIG. 3D. The second semiconductor structure 420 can be the first semiconductor chip 110 of FIG. 1, the memory die 202 of FIG. 2, or the second semiconductor structure 380 of FIG. 3D.

At least one opening 402 can be formed that extends through the second semiconductor structure 420 into the first semiconductor structure 410 along Z direction. The at least one opening 402 can have substantially same depths and widths, as illustrated in FIG. 4A. As noted above in reference to FIGS. 1-3D, the semiconductor structure (e.g., the first semiconductor structure 410) can include a conductive structure (e.g., the conductive structure 117 of FIG. 1, or the conductive structure 212 of FIG. 2). The opening 402 can be formed to expose a portion of the conductive structure.

The openings 402 can be formed by at least one etching operation. The etching operation can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof. Due to the etching characteristics, the first ends 402a of the opening 402 can be smaller than the second ends 402b of the opening 402, as illustrated in FIG. 4A. In some implementations, the width 403 of the first end 402a of the opening 402 along x direction is greater than or equal to 0.5 micrometer.

As illustrated in FIG. 4B, the opening 402 can be at least partially filled with a conductive ink liquid 404. In some implementations, the conductive ink liquid 404 is applied to the openings 402 using techniques, including, without limitation to, inkjet, micro-contact printing, screen printing, gravure printing, or flexographic printing. The conductive ink liquid 404 can have good fluidity and strong filling capability, allowing the openings 402 (including the first ends 402a of the openings 402) to be uniformly filled with the conductive ink liquid 404. This reduces or eliminates the formation of voids at the first ends 402a of the openings 402, thereby improving yield, performance and reliability of the semiconductor device 400.

The conductive ink liquid 404 can include conductive materials, binders and solvents. Without being limited to any particular theory, the solvents can be used to adjust the conductive ink’s viscosity, making it easier to apply through different printing techniques described herein and improving the fluidity of the conductive ink liquid 404. After the conductive ink liquid 404 is applied into the opening 402, the solvent can evaporate (e.g., during a sintering process described below), leaving behind the conductive materials and binders. The binders can be used to hold the conductive particles together.

In some implementations, conductive ink liquid 404 includes one or more conductive material and one or more organic polymer material. In some implementations, the one or more conductive material includes at least one of copper, silver or gold, and the one or more organic polymer material includes at least one of carbon, hydrogen, or oxygen. In an example, the conductive ink layer 302 includes copper. In another example, the conductive ink layer 302 includes silver. Examples of organic polymer materials include, without limitation to, poly(3,4-ethylenedioxythiophene) (PEDOT), polyaniline (PANI), polyethylene dioxythiophene (PEDOT), polyvinylidene fluoride (PVDF), polyurethane (PU), polyvinylpyrrolidone (PVP), polyvinyl alcohol (PVA), polyethylene glycol (PEG), polyimide (PI), ethyl cellulose, polystyrene (PS), polyethylene terephthalate (PET), epoxy resins, acrylic polymers, or any other suitable materials.

In some implementations, a percentage (e.g., mass percentage, and/or mole percentage) of the one or more organic polymer material in the conducive ink liquid is greater than a percentage (e.g., mass percentage, and/or mole percentage) of the one or more organic polymer material in the conducive ink layer that is formed after sintering. In some implementations, the percentage (e.g., mass percentage, and/or mole percentage) of the organic polymer material in the conducive ink liquid is greater than the percentage (e.g., mass percentage, and/or mole percentage) of the organic polymer material in the conducive ink layer by 2% to 5%. Without being limited to any particular theory, some of the organic polymer materials in the conductive ink liquid 404 may be evaporated during the sintering process described below in reference to FIG. 4C. In some implementations, the percentage (e.g., mass percentage, and/or mole percentage) of the organic polymer material in the conductive ink liquid 404 is about 5-10%, while the percentage (e.g., mass percentage, and/or mole percentage) of the organic polymer material in the conductive ink layer 406 that is formed after sintering is about 2-5%.

In some implementations, before at least partially filling the openings 402 with the conductive ink liquid 404, an isolation layer (e.g., the isolation layer 306 of FIGS. 3A-3C) can be formed. The isolation layer 306 can include dielectric materials including, but not limited to, silicon oxide, silicon nitride, silicon oxynitride, or any combination thereof. The isolation layer 306 can be deposited using one or more thin film deposition techniques, including, but not limited to, chemical vapor deposition (CVD), physical vapor deposition (PVD), plasma enhanced chemical vapor deposition (PECVD) atomic layer deposition (ALD), sputtering, or any combination thereof.

In some implementations, before at least partially filling the opening 402 with the conductive ink liquid 404, a part of the isolation layer 306 is removed (or punched through) at the bottom (e.g., the first end 402a) of the opening 402 to expose the underlying conductive structure (e.g., the conductive structure 117 of FIG. 1, or the conductive structure 212 of FIG. 2). Removing the part of the isolation layer 306 at the bottom of the opening 402 can involve one or more etching techniques described herein.

As illustrated in FIG. 4C, the conductive ink liquid 404 can be sintered to form a conductive ink layer 406 in the opening 402. The conductive ink layer 406 can be the conductive ink layer 302 of FIGS. 3A-3C. In some implementations, before or during sintering the conductive ink liquid 404, a process chamber that is used for sintering is at least partially filled with at least one of an inert gas or a reducing gas. Examples of inert gas include helium (He), nitrogen (N₂), and/or Argon (Ar), but not limited thereto. Examples of reducing gas include hydrogen (H₂), but not limited thereto.

In some implementations, the conductive ink liquid 404 is sintered at a temperature lower than a melting temperature of the conductive material (e.g., metal particles) in the conductive ink liquid 404. In some implementations, the conductive ink liquid 404 is sintered at a low temperature to avoid carbonization (e.g., a process where organic polymer materials can be converted into carbon or charcoal due to high temperature). In some implementations, the conductive ink liquid 404 is sintered at a temperature lower than 300 degree Celsius.

The duration of sintering can be inversely related to the temperature. For examples, when the sintering temperature is about 100° C, the sintering duration can range from 1 hour to 2 hours. In contrast, when the sintering temperature is about 200° C, the sintering duration can be reduced to about a few minutes. Therefore, implementations of the present disclosure can improve the efficiency of forming connection structures, thereby reducing production cycle times and manufacturing costs.

In some implementations, the conductive material in the conductive ink layer 406 is copper (Cu). The resistivity of the sintered Cu film can be close to that of pure Cu film formed by PVD.

In some implementations, the sintered conductive film (e.g., the conductive ink layer 406) can substantially fill the opening 402, as illustrated in FIGS. 3A and 3C.

In some implementations, the sintered conductive film (e.g., the conductive ink layer 406) can be formed on the sidewall of the opening 402 without fully filling the opening 402, as illustrated in FIG. 4C. In the example implementations where the sinter conductive film does not fully fill the opening 402, the sintered conductive film can be then used as a seed layer for electroplating more conductive materials into the opening 402. For example, if the conductive particles in the conductive ink liquid 404 is copper (Cu), the sintered Cu layer can be used as a seed layer, and more Cu material can be electroplated into the opening 402. Therefore, the opening 402 can be substantially filled with Cu. The electroplated conductive material can be referred to as a filler layer (e.g., filler layer 308 of FIG. 3B) in the present disclosure, or considered part of the conductive ink layer 406 (e.g., as illustrated in FIGS. 3A and 3C) in the present disclosure.

In the example implementations where the sinter conductive film does not fully fill the opening 402, the opening 402 can be filled with a filler layer (e.g., filler layer 308 of FIG. 3B) that includes a conductive material and/or an organic polymer material. The conductive material of the filler layer can be the same as or different from the conductive particles in the conductive ink layer 406. The filler layer can be formed using one or more thin film deposition techniques, including, but not limited to, electroplating (as described herein), chemical vapor deposition (CVD), physical vapor deposition (PVD), plasma enhanced chemical vapor deposition (PECVD) atomic layer deposition (ALD), sputtering, spin coating, printing, or any combination thereof.

It is to be understood that although not shown in FIGS. 4A-4C, before forming the conductive ink layer 406, a blocking layer (e.g., a blocking layer 304 of FIGS. 3A-3C) can be formed in the opening 402. As noted above, the blocking layer 304 can include at least one of titanium nitride (TiN), titanium (Ti), tantalum nitride (TaN) or tantalum (Ta). The blocking layer 304 can be formed using the one or more thin film deposition techniques described herein.

FIGS. 4A-4C illustrate an example process for forming connection structures in two semiconductor structures 410, 420 that are stacked together. Similar process techniques described in reference to FIGS. 4A-4C can be applied to form a semiconductor device with only one semiconductor structure or a semiconductor device with three or more semiconductor structures that are stacked together.

In some implementations, the openings 402 formed in the same etching operation can have the same depths, as illustrated in FIG. 4A. To form openings with different depths that extend into different semiconductor structures, a sequence of etching operations can be performed, and each subsequent etching operation may further extend depths of selective openings formed at a previous step. Referring now to FIG. 4D, in some implementations, to form the openings 412, 414, 416, 418, four etching operations may be performed:
the first etching operation can etch four initial openings that all extend in the first semiconductor structure 432, and the initial openings can have the same depths as the opening 412;
the second etching operation can be performed on three of the initial openings (e.g., #1, #2, #3 of FIG. 4D) to extend the depth of these initial openings into the second semiconductor structure 434. During this etching operation, the opening #4 can be covered by a protective layer. After the second etching operation, the openings #1, #2, #3 can have the same depths as the opening 414;
the third etching operation can be performed on the first and second openings (#1 and #2) to further extend their depths to the third semiconductor structure 436. During this etching operation, both openings #3, #4 can be covered by a protective layer. After the third etching operation, the openings #1, #2 can have the same depths as the opening 416; and
the last etching operation can be performed on only the first opening #1 to further extend its depth to the fourth semiconductor structure 438. During this etching operation, openings #2, #3, #4 can be covered by a protective layer. After the fourth etching operation, the depth of the opening #1 can be same as the depth of opening 418.

Therefore, openings 412, 414, 416, 418 with different depths can be formed. One ends (e.g., upper ends) of the openings 412, 414, 416, 418 can be coplanar or aligned with one another, and the other ends (e.g., lower ends) of the openings 412, 414, 416, 418 can expose a portion of a corresponding conductive structure 411, 413, 415, 417. For example, the lower end of the opening 412 can expose a portion of the conductive structure 411. The lower end of the opening 414 can expose a portion of the conductive structure 413. The lower end of the opening 416 can expose a portion of the conductive structure 415. The lower end of the opening 418 can expose a portion of the conductive structure 417.

After forming the openings 412, 414, 416, 418, the process steps described above in reference to FIGS. 4B and 4C can be performed to form connection structures with different depths, and the connection structures can be coupled to the corresponding conductive structures 411, 413, 415, 417.

It is to be understood that although FIG. 4D shows that only one opening is extended into a corresponding semiconductor structure, two or more openings can be formed that extend into the same semiconductor structure.

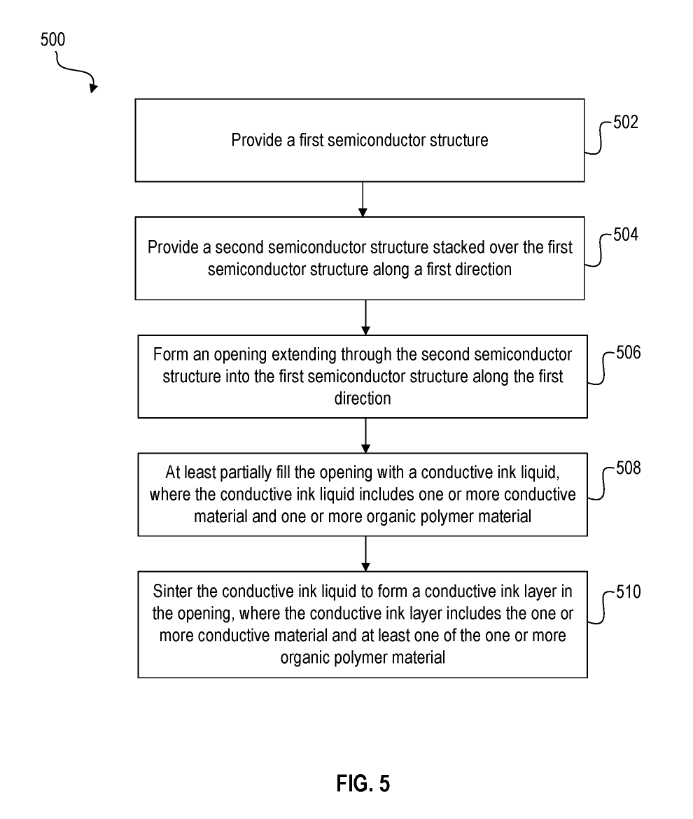

FIG. 5 illustrates a flow chart of a process of an example of method 500 to form a semiconductor device. The semiconductor device can be, e.g., the memory device 100 of FIG. 1, the semiconductor device 200 of FIG. 2, any one of the semiconductor chips 110, 120, 130, 140 of FIG. 1, any one of the memory dies 202, 204, 206, 208 of FIG. 2, the connection structure 300 of FIG. 3A, the connection structure 350 of FIG. 3B, the connection structure 300’ of FIG. 3C, connection structures 360, 365 of FIG. 3D, or the semiconductor device 400 of FIGS. 4A-4D.

At step 502, a first semiconductor structure is provided. The first semiconductor structure can be any one of the semiconductor chips 120, 130, 140 of FIG. 1, any one of the memory die 204, 206, 208 of FIG. 2, the first semiconductor structure 370 of FIG. 3D, the first semiconductor structure 410 of FIGS. 4A-4C, or any one of the semiconductor structures 434, 436, 438 of FIG. 4D.

At step 504, a second semiconductor structure is provided that is stacked over the first semiconductor structure along a first direction. The second semiconductor structure can be any corresponding one of semiconductor chips 110, 120, 130 of FIG. 1, any corresponding one of memory dies 202, 204, 206 of FIG. 2, the second semiconductor structure 380 of FIG. 3D, the second semiconductor structure 420 of FIGS. 4A-4C, or any corresponding one of semiconductor structures 432, 434, 436 of FIG. 4D. The first direction can be, e.g., Z direction of FIGS. 1-4D.

At step 506, an opening is formed that extends through the second semiconductor structure into the first semiconductor structure along the first direction. The opening can be, e.g., the opening 402 of FIGS. 4A-4C, or the opening 414 of FIG. 4D.

At step 508, the opening is at least partially filled with a conductive ink liquid, where the conductive ink liquid includes one or more conductive material and one or more organic polymer material. The conductive ink liquid can be, e.g., the conductive ink liquid of FIG. 4B.

At step 510, the conductive ink liquid is sintered to form a conductive ink layer in the opening, where the conductive ink layer includes the one or more conductive material and at least one of the one or more organic polymer material. The conductive ink layer can be, e.g., the conductive ink layer 302 of FIGS. 3A-3D, or the conductive ink layer 406 of FIG. 4C.

In some implementations, the method includes at least partially filling a process chamber with at least one of an inert gas or a reducing gas, where sintering the conductive ink liquid to form the conductive ink layer includes sintering the conductive ink liquid to form the conductive ink layer in the process chamber, as described above in reference to FIG. 4C.

In some implementations, sintering the conductive ink liquid to form the conductive ink layer includes: sintering the conductive ink liquid to form the conductive ink layer at a temperature lower than 300 degree Celsius, as described above in reference to FIG. 4C.

In some implementations, the one or more conductive material includes at least one of copper, silver or gold, and the one or more organic polymer material includes at least one of carbon, hydrogen, or oxygen.

In some implementations, a percentage (e.g., a mass percentage and/or a more percentage) of the one or more organic polymer material in the conducive ink liquid is greater than a percentage (e.g., a mass percentage and/or a more percentage) of the one or more organic polymer material in the conducive ink layer.

In some implementations, the method includes forming an isolation layer; forming a blocking layer between the isolation layer and the conductive ink layer in the opening; and forming a filler layer, where the conducive ink layer is between the filler layer and the blocking layer. The isolation layer can be, e.g., the isolation layer 306 of FIGS. 3A-3C. The blocking layer can be, e.g., the blocking layer 304 of FIGS. 3A-3D. The filler layer can be, e.g., the filler layer 308 of FIG. 3B.

In some implementations, the first semiconductor structure includes a conductive structure, and forming the opening extending through the second semiconductor structure into the first semiconductor structure includes: forming the opening extending through the second semiconductor structure into the first semiconductor structure to expose a portion of the conductive structure. The conductive structure can be, e.g., any corresponding one of the conductive structures 107, 117, 127, 137 of FIG. 1, any corresponding one of the conductive structures 210, 212, 214, 216 of FIG. 2, or any corresponding one of the conductive structures 411, 413, 415, 417 of FIG. 4D.

In some implementations, the method includes before at least partially filling the opening with the conductive ink liquid, removing the isolation layer at a first end of the opening, the first end of the opening being coupled to the first semiconductor structure. The first end of the opening can be, e.g., the first end 402a of the opening 402 of FIG. 4A.

In some implementations, forming the opening includes: forming the opening such that the opening includes a first end coupled to the first semiconductor structure and a second end opposite to the first end along the first direction, a width of the first end of the opening being smaller than a width of the second end of the opening along a second direction. The second end of the opening can be, e.g., the second end 402b of the opening 402 of FIG. 4A. The width of the first end of the opening can be, e.g., the width 403 of the first end 402a of the opening 402 of FIG. 4A. The width of the second end of the opening can be, e.g., the width 405 of the second end 402b of the opening 402. The second direction can be, e.g., X direction of FIGS. 1-4D.

In some implementations, forming the opening includes: forming the opening such that the width of the first end of the opening along the second direction is greater than or equal to 0.5 micrometer.

In some implementations, the method includes: providing a plurality of semiconductor structures including the first semiconductor structure and the second semiconductor structure, the plurality of semiconductor structures each having a conductive structure; and forming a plurality of openings including the opening, where the plurality of openings each has a first end and a second end opposite to the first end along the first direction, the first ends of the plurality of openings are aligned with one another, and the second end of each of the plurality of openings exposes a portion of the conductive structure of a corresponding one of the plurality of semiconductor structures, and where at least two of the plurality of openings have different height along the first direction, as described above in reference to FIGS. 1, 2, and 4A-4D.

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the memory device 100 of FIG. 1, the semiconductor device 200 of FIG. 2, any one of the semiconductor chips 110, 120, 130, 140 of FIG. 1, any one of the memory dies 202, 204, 206, 208 of FIG. 2, the connection structure 300 of FIG. 3A, the connection structure 350 of FIG. 3B, the connection structure 300’ of FIG. 3C, connection structures 360, 365 of FIG. 3D, or the semiconductor device 400 of FIGS. 4A-4D.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “some implementations,” “example implementations,” “one implementation,” “an implementation,” “an example implementation,” etc., indicate that the implementation described can include a particular feature, structure, or characteristic, but every implementation can not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature’s relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+-.10%, .+-.20%, or .+-.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

As used herein, the term “surrounded by” refers to at least partially surrounded by. For example, A is surrounded by B can refer to that A is at least partially surrounded by B.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first semiconductor structure;
a second semiconductor structure stacked over the first semiconductor structure along a first direction; and
a connection structure extending from the second semiconductor structure into the first semiconductor structure along the first direction, wherein the connection structure comprises a conductive ink layer, and the conductive ink layer comprises one or more conductive material and one or more organic polymer material.

2. The semiconductor device of claim 1, wherein the one or more conductive material is greater than 85% in the conductive ink layer.

3. The semiconductor device of claim 1, wherein the one or more conductive material comprises at least one of copper, silver or gold, and the one or more organic polymer material comprises at least one of carbon, hydrogen, or oxygen.

4. The semiconductor device of claim 1, wherein the connection structure comprises a first end coupled to the first semiconductor structure and a second end opposite to the first end along the first direction, and a width of the first end of the connection structure along a second direction is smaller than a width of the second end of the connection structure along the second direction.

5. The semiconductor device of claim 4, wherein the width of the first end of the connection structure along the second direction is greater than or equal to 0.5 micrometer.

6. The semiconductor device of claim 4, wherein a ratio of a height of the connection structure along the first direction to the width of the second end of the connection structure along the second direction is equal to or greater than 15.

7. The semiconductor device of claim 1, wherein the connection structure further comprises a filler layer at least partially surrounded by the conductive ink layer, and the filler layer comprises at least one of a conductive material or an organic polymer material.

8. The semiconductor device of claim 1, wherein the connection structure comprises an isolation layer and a blocking layer between the isolation layer and the conductive ink layer, and the blocking layer comprises at least one of titanium nitride (TiN), titanium (Ti), tantalum nitride (TaN) or tantalum (Ta).

9. The semiconductor device of claim 1, wherein the first semiconductor structure comprises a conductive structure, and the conductive ink layer of the connection structure is in contact with the conductive structure of the first semiconductor structure.

10. The semiconductor device of claim 1, wherein at least one of the first semiconductor structure and the second semiconductor structure comprises:
a memory array comprising a plurality of memory cells; and
a peripheral circuit coupled to the memory array and configured to control the memory array.

11. A method to form a semiconductor device, comprising:
providing a first semiconductor structure;
providing a second semiconductor structure stacked over the first semiconductor structure along a first direction;
forming an opening extending through the second semiconductor structure into the first semiconductor structure along the first direction;
at least partially filling the opening with a conductive ink liquid, wherein the conductive ink liquid comprises one or more conductive material and one or more organic polymer material; and
sintering the conductive ink liquid to form a conductive ink layer in the opening, wherein the conductive ink layer comprises the one or more conductive material and at least one of the one or more organic polymer material.

12. The method of claim 11, comprising:
at least partially filling a process chamber with at least one of an inert gas or a reducing gas,
wherein sintering the conductive ink liquid to form the conductive ink layer comprises sintering the conductive ink liquid to form the conductive ink layer in the process chamber.

13. The method of claim 11, wherein sintering the conductive ink liquid to form the conductive ink layer comprises:
sintering the conductive ink liquid to form the conductive ink layer at a temperature lower than 300 degree Celsius.

14. The method of claim 11, wherein the one or more conductive material comprises at least one of copper, silver or gold, and the one or more organic polymer material comprises at least one of carbon, hydrogen, or oxygen.

15. The method of claim 11, wherein a percentage of the one or more organic polymer material in the conducive ink liquid is greater than a percentage of the one or more organic polymer material in the conducive ink layer.

16. The method of claim 11, comprising:
forming an isolation layer;
forming a blocking layer between the isolation layer and the conductive ink layer in the opening; and
forming a filler layer, wherein the conducive ink layer is between the filler layer and the blocking layer.

17. The method of claim 11, wherein the first semiconductor structure comprises a conductive structure, and forming the opening extending through the second semiconductor structure into the first semiconductor structure comprises: forming the opening extending through the second semiconductor structure into the first semiconductor structure to expose a portion of the conductive structure.

18. The method of claim 11, wherein forming the opening comprises:
forming the opening such that the opening includes a first end coupled to the first semiconductor structure and a second end opposite to the first end along the first direction, a width of the first end of the opening being smaller than a width of the second end of the opening along a second direction.

19. The method of claim 18, wherein forming the opening comprises:
forming the opening such that the width of the first end of the opening along the second direction is greater than or equal to 0.5 micrometer.

20. A system, comprising:
a memory die comprising:
a first semiconductor structure;
a second semiconductor structure stacked over the first semiconductor structure along a first direction; and
a connection structure extending from the second semiconductor structure into the first semiconductor structure along the first direction, wherein the connection structure comprises a conductive ink layer, and the conductive ink layer comprises one or more conductive material and one or more organic polymer material; and
a base die coupled to the memory die,
wherein the base die and the memory die are stacked along the first direction.
